(19) United States
(12) Patent Application Publication
(10) Pub. No.: US 2006/0023544 A1
(43) Pub. Date: Feb. 2, 2006

(54) Semiconductor device

(75) Inventor: Katsuhiro Yamada, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/006,590

(22) Filed: Dec. 8, 2004

(30) Foreign Application Priority Data
Jul. 30, 2004 (JP) 2004-224310

(51) Int. Cl. G11C 7/00

(52) U.S. Cl. 365/222

(57) ABSTRACT

A functional block has a normal operation mode and a test mode. An external signal terminal receives an operation inhibition signal which is activated to inhibit the normal operation of the functional block. An external clock terminal receives an external clock. A test mode control circuit shifts the functional block from the normal operation mode to the test mode while the operation inhibition signal is in an activated state and the test mode control circuit is receiving the external clock. Accordingly, the semiconductor testing apparatus inputs the operation inhibition signal in a fixed activated state to the external signal terminal and inputs the external clock to the external clock terminal, thereby shifting the functional block to the test mode.

### CROSS REFERENCE TO RELATED APPLICATION

This application is based upon and claims the benefit of priority from Japanese Patent Application No. 2004-224310, filed on Jul. 30, 2004, the entire contents of which are incorporated herein by reference.

### BACKGROUND OF THE INVENTION

1. Field of the Invention

The present invention relates to a semiconductor device, and particularly to a technique to test a semiconductor device.

2. Description of the Related Art

There are two types of semiconductor devices as FRAMs and DRAMs, i.e., the parallel interface type having an I/O for data of multiple bits (i.e. 8-bit or 16-bit), and the serial interface type having an I/O for data of a single bit. Since the mainstream of semiconductor devices is the parallel interface type, semiconductor testing apparatus (testers or burn-in systems) is mainly configured to meet the needs for testing parallel interface type semiconductor devices.

Japanese Unexamined Patent Application Publication No. Hei 4-339400 discloses a technique to stably and credibly perform the aging (or burn-in) of a serial interface type semiconductor device. The semiconductor device disclosed in the above reference includes an address register to latch an address signal, an address decoder to decode the address signal latched by the address register, and a memory-cell array in which memory cells designated by the decoded signals of the address decoder are sequentially activated, and it further includes a means to determine whether it is in a test mode or not based on a clock signal and signals of a predetermined level (data signal and chip-select signal), and a means to count the clock signal and input the counted value to the address register as an address signal when it is determined to be in the test mode.

When a testing of a serial interface type semiconductor device is attempted using a semiconductor testing apparatus configured for testing a parallel interface type semiconductor device, there will be a problem since it is difficult to perform the test as the test resources cannot be utilized effectively. Burn-in apparatus, especially, is not well supported in terms of both hardware and software when compared to testers, so that it cannot test both the parallel and serial interface types in a versatile manner. Accordingly, the development of high-end hardware and software corresponding to the serial interface type semiconductor device is required, resulting in the increase in the cost of a product.

### SUMMARY OF THE INVENTION

It is an object of the invention to provide a semiconductor device which can be tested easily without the need of developing high-end hardware and software.

According to a first aspect of the semiconductor device according to the invention, a functional block has a normal operation mode and a test mode. An external signal terminal receives an operation inhibition signal which is activated to inhibit the normal operation of the functional block. An external clock terminal receives an external clock. A test mode control circuit shifts the functional block from the normal operation mode to the test mode while the operation inhibition signal is in an activated state and the test mode control circuit is receiving the external clock. Accordingly, the semiconductor testing apparatus inputs the operation inhibition signal in a fixed activated state to the external signal terminal and inputs the external clock to the external clock terminal, thereby shifting the functional block to the test mode. Furthermore, the external signal terminal receiving the operation inhibition signal is generally clamped on the activation side of the operation inhibition signal inside the semiconductor device so that just inputting the external clock to the external clock terminal enables the functional block to shift to the test mode even while the external signal terminal is in an open state. Accordingly, the semiconductor device can be tested easily without the need for the development of high-end hardware and software. As a result, it is possible to reduce the product cost of the semiconductor device.

In a preferred example of the first aspect of the semiconductor device according to the invention, a holding circuit of the test mode control circuit holds in advance flag information indicating permission/inhibition for the functional block to shift from the normal operation mode to the test mode, and outputs the flag information while the test mode control circuit is receiving the external clock. A control circuit of the test mode control circuit activates the test mode signal when the operation inhibition signal is in the activated state and the flag information from the holding circuit indicates permission. In response to the activation of the test mode signal, the functional block shifts from the normal operation mode to the test mode. This can facilitate the configuration of the test mode control circuit which allows the functional block to shift from the normal operation mode to the test mode.

According to the preferred example of the first aspect of the semiconductor device of the invention, the flag information held in the holding circuit of the test mode control circuit is rewritable. Therefore, it is preventable that the functional block shifts to the test mode during a user's use of the semiconductor device by testing the semiconductor device and then rewriting, prior to shipment, the flag information in the holding circuit to indicate the inhibition of shifting the functional block to the test mode.

In the preferred example of the first aspect of the semiconductor device according to the invention, the functional block is a memory block having nonvolatile memory cells. The holding circuit of the test mode control circuit has memory cells identical to those of the memory block in order to hold the flag information. Accordingly, the holding circuit can be formed to have the same semiconductor device structure as the memory block, thereby contributing to the simplification of the semiconductor device manufacturing.

According to the second aspect of the semiconductor device of the present invention, a functional block has a normal operation mode and a test mode. An external clock terminal receives an external clock having a variable duty ratio. A delay circuit outputs a delayed clock which is generated by delaying the external clock. An instruction code generator sequentially accepts levels of the external clock in synchronization with transition edges of the delayed clock, and outputs them as an instruction code. A test mode control circuit shifts the functional block from the normal operation mode to the test mode when the instruction code designates the test mode. Accordingly, the semiconductor testing apparatus just changes in every cycle the duty ratio of the external clock to be inputted into the external clock terminal, thereby enabling the shifting of the functional block to the test mode. Thus, the semiconductor device can be easily tested without the need for developing high-end hardware and software. This results in reduction of the product cost of the semiconductor device. Furthermore, the duty ratio of the external clock is generally set to a fixed value (for example, 50%) for a user's operation to the semiconductor device, so that instruction codes outputted from the instruction code generator will be always the same. Accordingly, the holding circuit holds codes other than the same instruction codes in advance, so that it can be avoided that the functional block shifts to the test mode during a user's use of the semiconductor device.

In a preferred example of the second aspect of the semiconductor device according to the invention, the holding circuit of the test mode control circuit holds in advance a code which indicates the test mode, and outputs the code. A control circuit of the test mode control circuit activates the test mode signal in response to a coincidence of the instruction code and the code from the holding circuit. The functional block shifts from the normal operation mode to the test mode in response to the activation of the test mode signal. This enables easy construction of the test mode control circuit which allows the functional block to shift from the normal operation mode to the test mode.

In the preferred example of the second aspect of the semiconductor device according to the invention, codes held in the holding circuit of the test mode control circuit are rewritable. Accordingly, it is avoidable that the functional block shifts to the test mode during a user's operation to the semiconductor device, by testing the semiconductor device and then rewriting, prior to shipment, the codes held in the holding circuit not to indicate the test mode.

In the preferred embodiment of the second aspect of the semiconductor device according to the invention, the functional block is a memory block having nonvolatile memory cells. The holding circuit of the test mode control circuit has memory cells identical to those of the memory block in order to hold the code. Accordingly, the holding circuit can be formed to have the same semiconductor device structure as the memory block, thereby contributing to the simplification of the semiconductor device manufacturing.

In the preferred example of the second aspect of the semiconductor device according to the invention, the functional block has a plurality of test modes. When the instruction code indicates any one of the plurality of test modes, the test mode control circuit allows the functional block to shift from the normal operation mode to the corresponding the indicated one of the test modes. The semiconductor testing apparatus inputs the external clock to the external clock terminal while changing the duty ratio in accordance with the plurality of test modes, thereby realizing simultaneous shifting of the functional block to a plural test modes that are operable in parallel.

In the preferred example of the second aspect of the semiconductor device according to the invention, the holding circuit of the test mode control circuit holds in advance and outputs a plurality of codes corresponding to the plurality of test modes. In response to a coincidence of the instruction code and any of the plurality of codes from the holding circuit, the control circuit of the test mode control circuit activates one of the plurality of test mode signals in correspondence with the coinciding code. In response to the activation of any of the plurality of test mode signals, the functional block shifts from the normal operation mode to the test mode corresponding to the activated test mode signal. In this way, it is able to easily construct the test mode control circuit which shifts the functional block from the normal operation mode to the test mode.

In the preferred example of the second aspect of the semiconductor device according to the invention, the test mode control circuit is able to control the test-mode shifting operation on the functional block when the instruction code indicates the permission to the test mode, and shifts the functional block from the normal operation mode to the test mode when a subsequent instruction code designates the test mode. Accordingly, the functional block will never shift to the test mode unless the instruction code indicates a test-mode entry. As a result, it is avoidable with reliability that the functional block shifts to the test mode during a user's operation to the semiconductor device.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a block diagram showing a first principle of the present invention;

FIG. 2 is a block diagram showing a second principle of the present invention;

FIG. 3 is a block diagram showing a first embodiment of the present invention;

FIG. 4 is a block diagram showing an exemplary system using the semiconductor memory of FIG. 3;

FIG. 5 is a timing chart showing the write operation of the semiconductor memory of FIG. 3 during a normal operation mode;

FIG. 6 is a timing chart showing the read operation of the semiconductor memory of FIG. 3 during a normal operation mode;

FIG. 7 is a block diagram showing a second embodiment of the present invention;

FIG. 8 is a timing chart showing the shifting operation of the semiconductor memory of FIG. 7 to the test mode;

FIG. 9 is a block diagram showing a third embodiment of the present invention;

FIG. 10 is a timing chart showing the shifting operation of the semiconductor memory of FIG. 9 to the test mode;

FIG. 11 is a timing chart showing the shifting operation of the semiconductor memory of FIG. 9 to the test mode;

FIG. 12 is a timing chart showing the shifting operation of the semiconductor memory of FIG. 9 to the test mode; and

FIG. 13 is a block diagram showing a fourth embodiment of the present invention.

### DESCRIPTION OF THE PREFERRED EMBODIMENTS

Hereinafter, a description is given of embodiments of the invention with reference to the accompanying drawings. In the drawings, a double circle indicates an external terminal, and a thick arrow indicates a signal including multiple bits. Signals inputted or outputted to/from the external terminals are indicated by identical numerals as the corresponding external terminals.

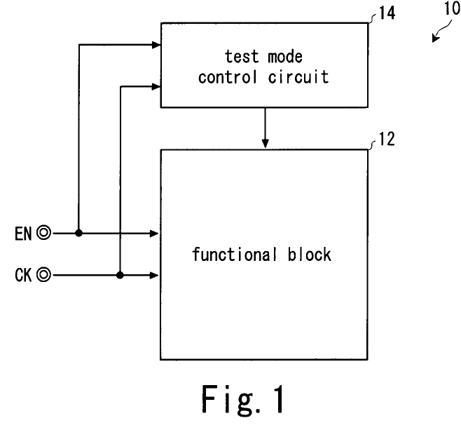

FIG. 1 shows a first principle of the invention. A semiconductor device 10 includes an external signal terminal EN, an external clock terminal CK, a functional block 12, and a test mode control circuit 14. The functional block 12 has a normal operation mode and a test mode. The external signal terminal EN receives an operation inhibition signal EN which is activated to inhibit the normal operation of the functional block 12. The external clock terminal CK receives an external clock CK. The test mode control circuit 14 shifts the functional block 12 from the normal operation mode to the test mode when the operation inhibition signal EN is in an activated state and the external clock CK is being received.

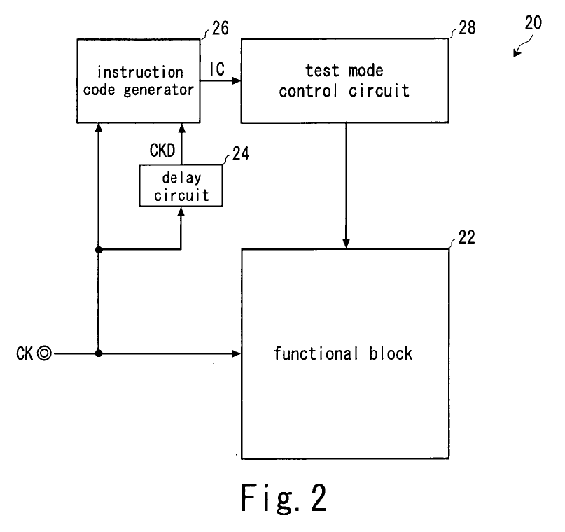

FIG. 2 shows a second principle of the invention. A semiconductor device 20 includes an external clock terminal CK, a functional block 22, a delay circuit 24, an instruction code generator 26, and a test mode control circuit 28. The functional block 22 has a normal operation mode and a test mode. The external clock terminal CK receives an external clock CK having a variable duty ratio. The delay circuit 24 outputs a delayed clock CKD which is the external clock CK that has been delayed to the instruction code generator 26. The instruction code generator 26 sequentially captures the external clock CK by having its level synchronized with the transition edges of the delayed clock CKD, and outputs to the test mode control circuit 28 as an instruction code IC. The test mode control circuit 28 shifts the functional block 22 from the normal operation mode to the test mode when the instruction code indicates the test mode.

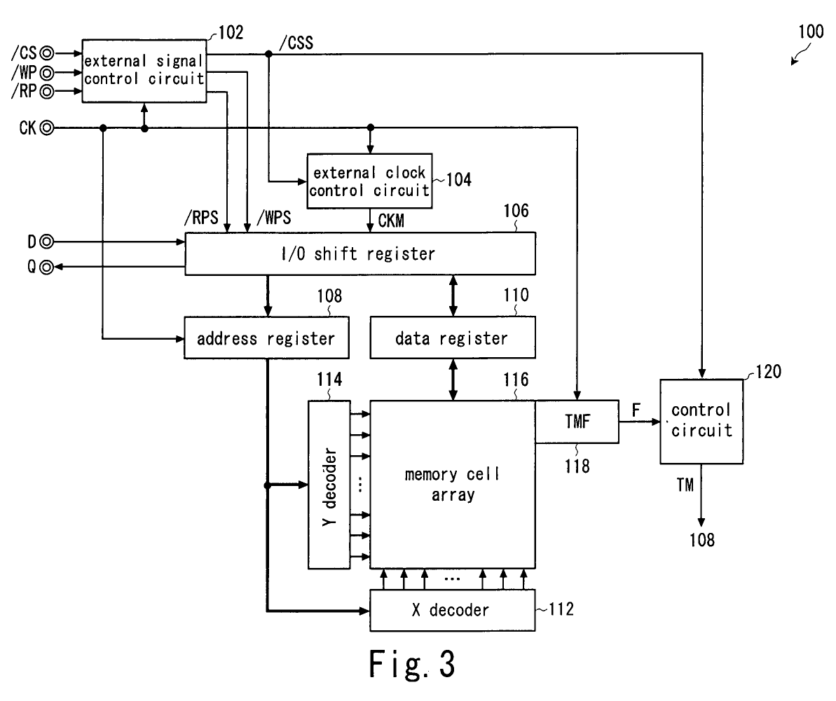

FIG. 3 shows a first embodiment of the invention. The semiconductor device of the invention is constructed as a serial interface type semiconductor memory 100 (i.e. FRAM). The semiconductor memory 100 includes an external signal control circuit 102, an external clock control circuit 104, an I/O shift register 106, an address register 108, a data register 110, an X-decoder 112, a Y-decoder 114, a memory cell array 116, a test mode flag (TMF) 118, a control circuit 120, external signal terminals /CS, /RP, /WP, an external clock terminal CK, a 1-bit data input terminal D and a 1-bit data output terminal Q.

The external signal control circuit 102 receives a chip-select signal /CS, a read-protect signal /RP and a write-protect signal /WP (operation inhibition signal) that are inputted, respectively, via the external signal terminals /CS, /RP and /WP in synchronization with the external clock CK which is inputted via the external clock terminal CK. The external signal control circuit 102 outputs the read-protect signal /RP and the write-protect signal /WP, received in synchronization with the external clock CK, to the I/O shift register 106 as a read-protect signal /RPS and a write-protect signal /WPS. Furthermore, the external signal control circuit 102 outputs the chip-select signal /CS, received in synchronization with the external clock CK, to the external clock control circuit 104 and the control circuit 120 as a chip-select signal /CSS. The external terminals /CS, /RP and /WP are clamped on the active sides of, respectively, the chip-select signal /CS, read-protect signal /RP and write-protect signal /WP, within the semiconductor memory 100.

The external clock control circuit 104 outputs the external clock CK to the I/O shift register 106 as a clock CKM when the chip-select signal /CSS outputted from the external signal control circuit 102 is “0” (active level). The external clock control circuit 104 locks the clock CKM to “0, when the chip-select signal /CSS is “1” (non-active level), and masks the input of the external clock CK to the I/O shift register 106.

The I/O shift register 106, when the write-protect signal /WPS outputted from the external signal control circuit 102 is “1” (non-active level), sequentially receives input data D inputted via the data input terminal D in synchronization with the clock CKM outputted from the external clock control circuit 104, and writes the register value in the address register 108 or the data register 110. The I/O shift register 106, when the read-protect signal /RPS outputted from the external signal control circuit 102 is “1” (non-active level), sequentially receives input data D inputted via the data input terminal D in synchronization with the clock CKM, and writes the register value in the address register 108. The I/O shift register 106, then, reads the register value from the data register 110, and outputs the read register value via the data output terminal Q in synchronization with the clock CKM as an output data Q.

The address register 108, for example, is a 16-bit register, and the register value is set by the I/O shift register 106. The address register 108 also acts as a 16-bit counter, and where the test mode signal TM outputted from the control circuit 120 is activated to “1”, increments the counter value in synchronization with the external clock CK as being in the test mode. The data register 110, for example, is an 8-bit register, and outputs the register value set by the I/O shift register 106 to the memory cell array 116, or the register value set by the memory cell array 116 to the I/O shift register 106.

The X-decoder 112 and Y-decoder 114 decode, respectively, i.e. the lower 8 bits and the upper 8 bits of the register value of the address register 108, and select a memory cell of the memory cell array 116. The memory cell array 116 reads out the data from the memory cell selected by the X-decoder 112 and the Y-decoder 114 and writes the data into the data register 110, or, writes the register value of the data register 110 into the memory cell selected by the X-decoder 112 and the Y-decoder 114.

The test mode flag 118 is constituted of identical memory cells as the memory cells of the memory cell array 116, and holds preset data (flag information) indicating permission/inhibition of the transition from the normal operation mode to the test mode. The data held by the test mode flag 118 is set at “1” when the semiconductor memory 100 is permitted to transit from the normal operation mode to the test mode, and set at “0” when the semiconductor memory 100 is inhibited from transiting from the normal operation mode to the test mode. The test mode flag 118 outputs the data to the control circuit 120 as a flag signal F while it receives the external clock CK. The test mode flag 118 allows reading and writing of the data it holds in the same manner as the access to the memory cell array 116, and the held data is set at “1” during i.e. probe test of the semiconductor memory 100. Furthermore, in order to inhibit the setting of the test mode flag 118 by a user after shipping of the semiconductor memory 100, an address which inhibits the user access is allocated to the test mode flag 118.

The control circuit 120 generates a test mode signal TM based on the chip-select signal /CSS outputted from the external signal control circuit 102 and the flag signal F outputted from the test mode flag 118, and outputs it to the address register 108. More specifically, the control circuit 120 activates the test mode signal TM to “1” when the chip-select signal /CSS and the flag signal F are, respectively, “0” and “1”. Upon this, the address register 108 starts a count-up operation, and the memory cells of the memory cell array 116 are sequentially activated. That is, the semiconductor memory 100 shifts from the normal operation mode to the test mode (address-increment test mode). During any other conditions, the control circuit 120 holds the test mode signal TM to “0”.

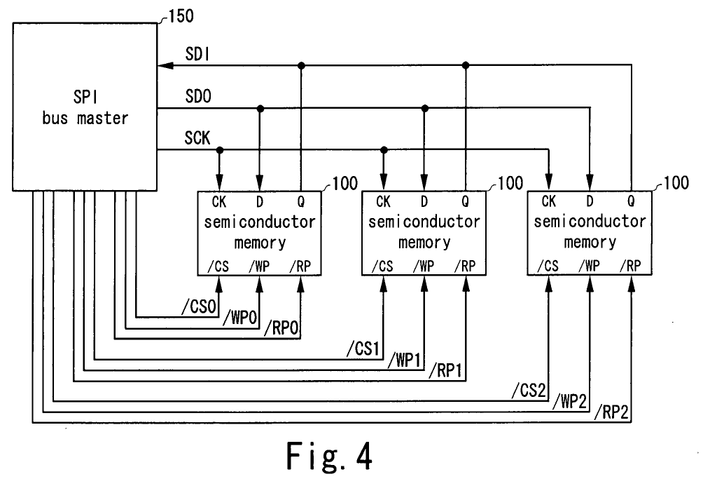

FIG. 4 shows an exemplary system which uses the semiconductor memory 100 of FIG. 3. In this system, three semiconductor memories 100 are connected to an SPI (Serial Peripheral Interface) bus. The SPI bus master 150 commonly outputs the external clock CK and the output data SDO to the external clock terminals CK and data input terminals D of the tree semiconductor memories 100. The SPI bus master 150 commonly receives input data SDI from the data output terminals Q of the three semiconductor memories 100.

Furthermore the SPI bus master 150, in order to control the access to the three semiconductor memories 100, outputs chip-select signals /CS0-/CS2, read-protect signals /RP0-/RP2, and write-protect signals /WP0-/WP2, respectively corresponding to the three semiconductor memories 100. Each of the chip-select signals /CS0-/CS2 is activated from “1” to “0” when the corresponding semiconductor memory 100 is being accessed. Each of the read-protect signals /RP0-/RP2 is deactivated from “0” to “1” when the corresponding semiconductor memory 100 is read-accessed. Each of the write-protect signals /WP0-/WP2 is deactivated from “0” to “1” when the corresponding semiconductor memory 100 is write-accessed.

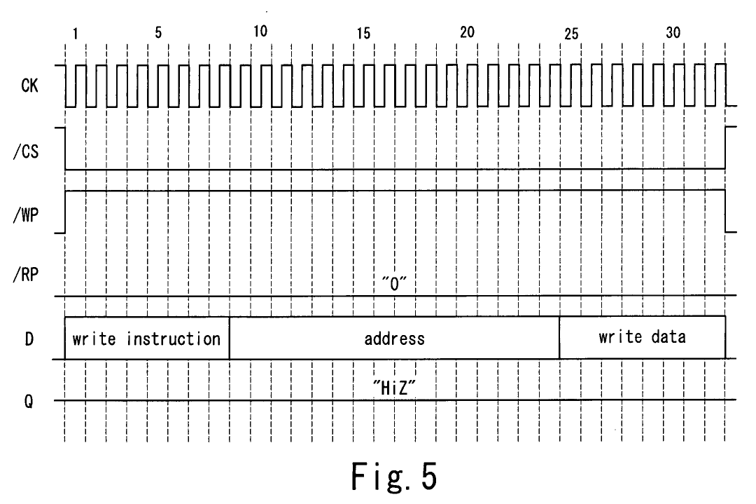

FIG. 5 shows the write operation in the normal operation mode within the semiconductor memory 100 of FIG. 3. If the semiconductor memory 100 determines that the first eight-bit instruction code of the input data D which is sequentially inputted to the data input terminal D in synchronization with the external clock is a write instruction, it sequentially writes subsequent 8-bit data in eight memory cells designated by the subsequent 16-bit address when the chip-select signal /CS and the write-protect signal /WP are “0” and “1” respectively.

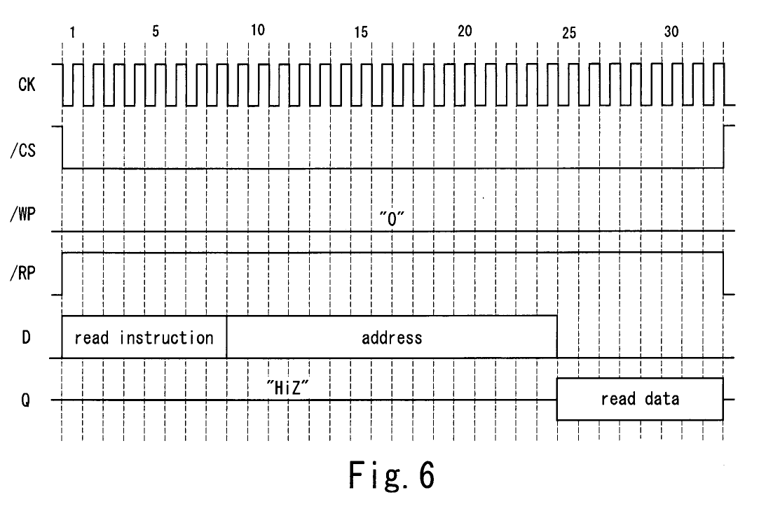

FIG. 6 shows the read operation in the normal operation mode within the semiconductor memory 100 of FIG. 3. If the semiconductor memory 100 determines that the first 8-bit instruction code of the input data D which is sequentially inputted to the data input terminal D in synchronization with the external clock CK is a read instruction, it sequentially outputs the data held by eight memory cells designated by the subsequent 16-bit address from the data output terminal Q when the chip-select signal /CS and the read-protect signal /RP are “0” and “1” respectively.

The semiconductor memory 100 having the above configuration can be shifted from the normal operation mode to the test mode only by inputting the external clock CK to the external clock terminal CK without the necessity of providing any special test mode terminal for receiving a test mode signal. Accordingly, the testing of the semiconductor memory 100 may simply be performed without requiring the development of high-end hardware and software. Furthermore, i.e. by shipping the semiconductor memory 100 after initializing the data held in the test mode flag 118 to “0” which indicates inhibition of shifting the semiconductor memory 100 to the test mode, after the functional test of the semiconductor memory 100, shifting of the semiconductor memory 100 to the test mode may be avoided during a user's use of the semiconductor memory 100.

As described heretofore, according to the first embodiment, the semiconductor memory 100 may be shifted to the test mode only by inputting the external clock CK to the clock terminal CK to simply perform the testing of the semiconductor memory 100 without the need for developing high-end hardware and software. As a result, the product cost of the semiconductor memory 100 may be reduced. In addition, by the initializing the test mode flag 118 during pre-shipment test, the shifting of the semiconductor memory 100 to the test mode may be avoided during the use of the semiconductor memory 100 by a user.

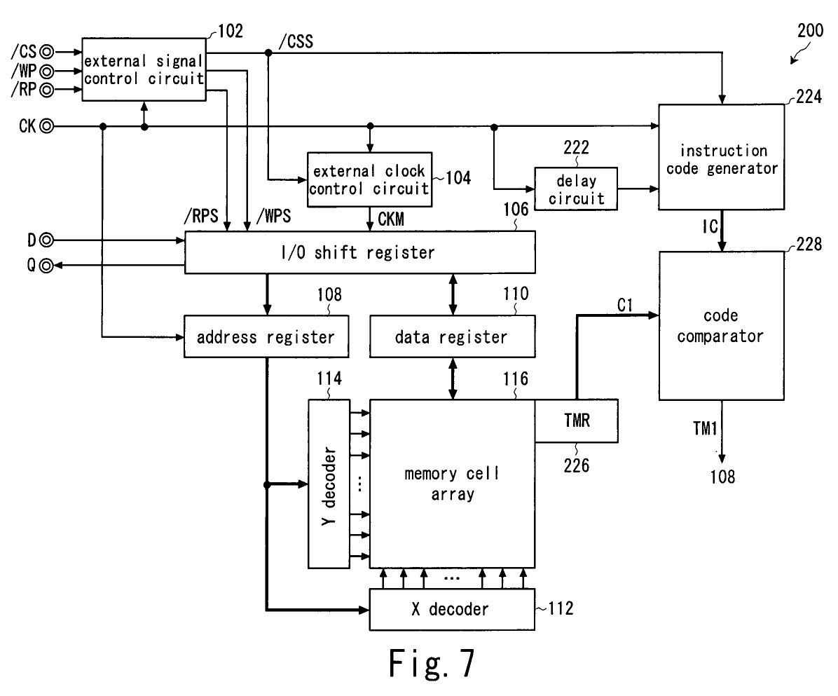

FIG. 7 shows a second embodiment of the invention. Any elements identical to those described according to the first embodiment will be indicated by the identical numerals and detailed description therefor will be omitted. In addition, the semiconductor device of the invention is constructed as a serial interface type semiconductor memory 200 (i.e. FRAM) similar to the first embodiment.

The semiconductor memory 200 includes the external signal control circuit 102, the external clock control circuit 104, the I/O shift register 106, the address register 108, the data register 110, the X-decoder 112, the Y-decoder 114, the memory cell array 116, the external signal input terminal /CS, /RP, /WP, the external clock terminal CK, the data input terminal D and the data output terminal Q of the first embodiment (FIG. 3), and further includes a delay circuit 222, an instruction code generator 224, a test mode register (TMR) 226 and a code comparator 228.

The delay circuit 222 includes, for example, an inverter row in an even number of stages, and it delays the external clock CK for a predetermined amount of time, and outputs it to the instruction code generator 224 as a delayed clock CKD. The instruction code generator 224 is i.e. an 8-bit shift register, which sequentially receives the levels of the external clock CK in synchronization with the transition edges (i.e. rising edges) of the delayed clock CKD. The instruction generation circuit 224 outputs a register value to the code comparator 228 as an instruction code IC (8 bits). The test mode register 226 is i.e. an 8-bit register, which is constructed from memory cells that are identical to the memory cells of the memory cell array 116, in the similar manner as that of the test mode flag 118 of the first embodiment. The test mode register 226 outputs a register value to the code comparator 228 as an 8-bit code C1. The test mode register 226 is capable of reading and writing of the register values as well as accessing to the memory cell array 116. At the time of i.e. the prove test of the semiconductor memory 200, the test mode register 226 is preset to have a register value (“10101100”) which indicates an address-decrement test mode. Also, in order to inhibit the setting of the register value of the test mode register 226 by a user after the shipment of the semiconductor memory 200, an address which inhibits user access is allocated to the test mode register 226.

The code comparator 228 compares the instruction code IC outputted from the instruction code generator 224 and the code C1 outputted from the test mode register 226, and when they match, activates the test mode signal TM1 for the address register 108 from “0” to “1”. Upon this, the address register 108 starts a count-down operation and memory cells of the memory cell array 116 are sequentially activated. In any other conditions, the code comparator 228 keeps the test mode signal TM1 at “0”.

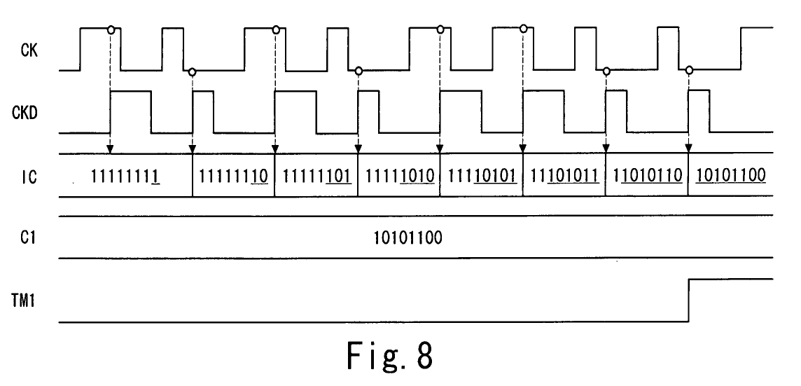

FIG. 8 shows the test-mode shifting operation of the semiconductor memory 200 of FIG. 7. When the external clock CK is inputted to the external clock terminal CK while changing its duty ratio sequentially to 50%, 25%, 50%, 25%, 50%, 50%, 25% and 25% in each cycle, the levels of the external clock CK sequentially received by the instruction code generator 224 in synchronization with the rising edges of the delayed clock CKD would be “1”, “0”, “1”, “0”, “1”, “1”, “0” and “0”. Accordingly, the instruction codes IC outputted from the instruction code generator 224 would sequentially vary to “11111111”, “11111110”, “11111101”, “11111010”, “11110101”, “11101011”, “11010110” and “10101100” in synchronization with the rising edges of the delayed clock CKD. The code C1 outputted from the test mode register 226 is “10101100”, so that when the instruction code IC is varied to “10101100”, the test mode signal TM1 outputted from the code comparator is activated from “0” to “1”. Upon this, the address register 108 starts the count-down operation, that is, the semiconductor memory 100 shifts from the normal operation mode to the address-decrement test mode.

Since the duty ratio of the external clock CK during the use of the semiconductor memory 200 by a user is typically constant at 50%, the instruction code IC outputted from the instruction code generator 224 is always “11111111”. Accordingly, by setting any register value other than this value (i.e. “10101100”) to the test mode register 226, the semiconductor memory 200 will never be shifted to the test mode during the use of the semiconductor memory 200 by a user.

As explained heretofore, in the second embodiment, the semiconductor memory 200 may be shifted to the test mode only by changing the duty ratio of the external clock, and the semiconductor memory 200 may easily be tested without the need for developing high-end hardware and software. As a result, the product cost of the semiconductor memory 200 may be reduced. Furthermore, since the duty ratio of the external clock CK during the use of the semiconductor memory 200 by a user is typically constant at 50%, the instruction code is always the same. Thus, by setting any register value other than this value to the test mode register 226, the semiconductor memory 200 to be shifted to the test mode may be avoided during the use of the semiconductor memory 200 by a user.

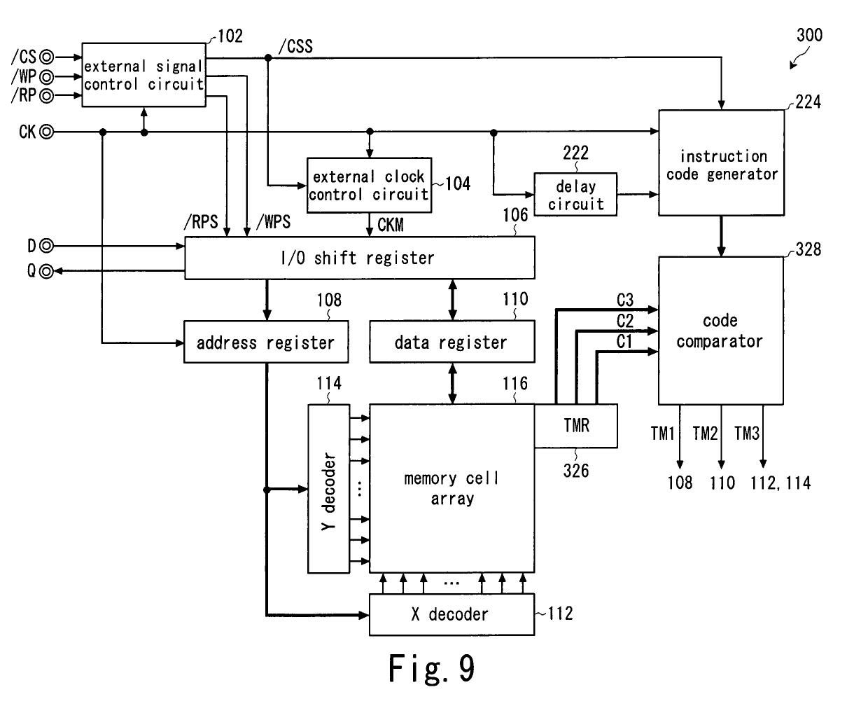

FIG. 9 is the third embodiment of the invention. Any elements identical to those described according to the first and second embodiment will be indicated by the identical numerals and detailed description therefor will be omitted. In addition, the semiconductor device of the invention is constructed as a serial interface type semiconductor memory 300 (i.e. FRAM) similar to the first embodiment. The semiconductor memory 300 has a test mode register 326 and a code comparator 328 in place of the test mode register 226 and the code comparator 228 of the second embodiment (FIG. 7). Any other parts of the configuration of the semiconductor memory 300 are identical to that of the semiconductor memory 200 of the second embodiment.

The test mode register 326 is i.e. a 24-bit register which includes memory cells identical to the memory cells of the memory cell array 116, in the same manner as the test mode register 226 of the second embodiment. The test mode register 326 outputs register values to the code comparator 328 as three 8-bit codes C1-C3. Furthermore, the test mode register 326 is capable of reading and writing the register values in the same way as accessing to the memory array 116. For example, at the time of the prove test of the semiconductor memory 300, the test mode register 326 is preset with register values including a value indicating the address-decrement test mode (“10101100”), a value indicating a test-pattern-link test mode (“10000010”) and a value indicating an address-degeneration test mode (“10000100”). In the test-pattern-link test mode, the data register 110 performs a write operation to a memory cell that is being selected by the X-decoder 112 and the Y-decoder 114 with the lower 8 bits of the register value of the address register 108 as the write data. In the address-degeneration test mode, the X-decoder 112 and the Y-decoder 114 simultaneously select memory cells whose lower 14 bits are allocated to an identical address. Furthermore, in order to inhibit a user from setting the register values of the test mode register 326 after the shipment of the semiconductor memory 300, an address which inhibits user access is allocated to the test mode register 326.

The code comparator 328 compares the instruction code IC from the instruction code generator 224 with the codes C1-C3 from the test mode register 326, and activates the test mode signal TM1 to be outputted to the address register 108 from “0” to “1” in response to the matching of the instruction code IC and the code C1. Upon this, the address register 108 starts a count-down operation, and the memory cells of the memory cell array 116 are sequentially activated. The code comparator 328 also activates the test mode signal TM2 to be outputted to the data register 110 from “0” to “1” in response to the matching of the instruction code IC and the code C2. Upon this, the data register 110 performs a writing operation of the lower 8 bits of the register value of the address register 108 to the memory cell array 116 as a write-data. The code comparator 328 activates the test mode signal TM3 to be outputted to the X-decoder 112 and the Y-decoder 114 from “0” to “1” in response to the matching of the instruction code IC and the code C3. Upon this, the X-decoder 112 and the Y-decoder 114 simultaneously select memory cells, the lower 14 bits of which are allocated to an identical address.

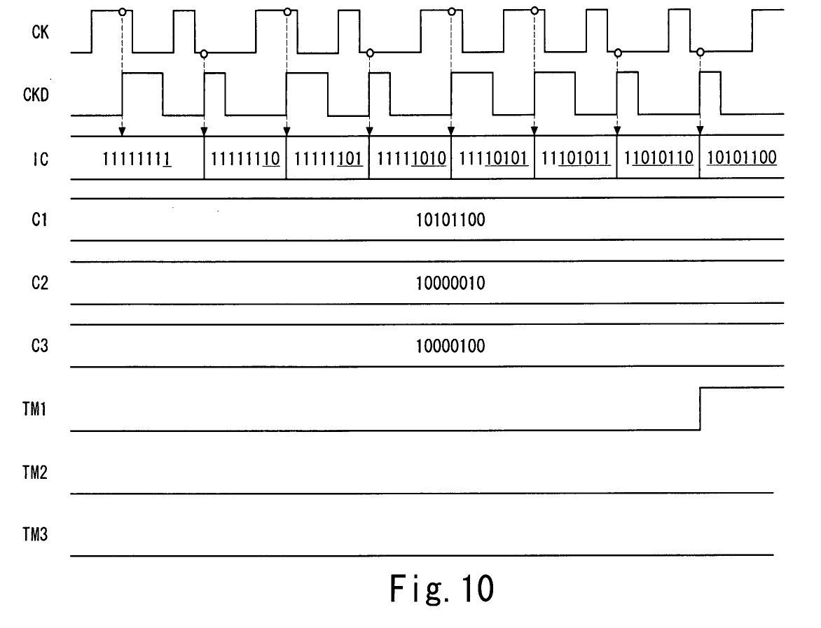

FIG. 10 through 12 show the test-mode shifting operation of the semiconductor memory 300 of FIG. 9.

First of all, as shown in FIG. 10, when the external clock CK is inputted to the external clock terminal CK while sequentially changing its duty ratio to 50%, 25%, 50%, 25%, 50%, 50%, 25% and 25% in every cycle, levels of the external clock CK sequentially received in synchronization with the rising edges of the delayed clock CKD within the instruction code generator 224 will be “1”, “0”, “1”, “0”, “1”, “1”, “0” and “0”. Therefore, the instruction code IC outputted from the instruction code generator 224 will sequentially change to “11111111”, “11111110”, “11111101” “11111010”, “11110101”, “11101011”, “11010110” and “10101100” in synchronization with the rising edges of the delayed clock CKD. Since the code C1 outputted from the test mode register 326 is “10101100”, the test mode signal TM1 outputted from the code comparator 328 is activated from “0” to “1” when the instruction code IC changes to “10101100”. Upon this, the semiconductor memory 300 shifts from the normal operation mode to the address-decrement test mode.

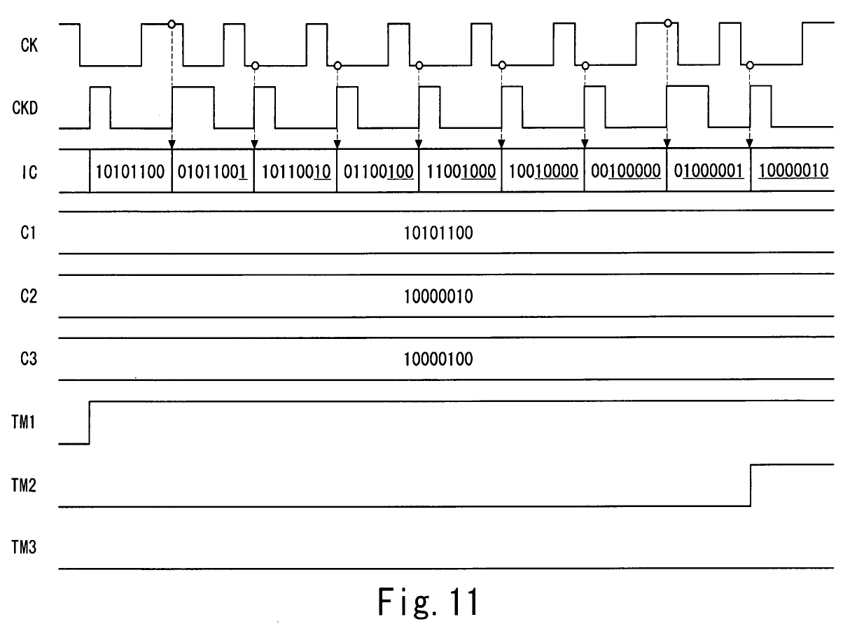

Subsequently, as shown in FIG. 11, when the external clock CK is inputted to the external clock terminal CK while sequentially changing its duty ratio to 50%, 25%, 25%, 25%, 25%, 25%, 50% and 25% in every cycle, levels of the external clock CK sequentially received in synchronization with the rising edges of the delayed clock CKD within the instruction code generator 224 will be “1”, “0”, “0”, “0”, “0”, “0”, “1” and “0”. Accordingly, the instruction code IC outputted from the instruction code generator 224 will sequentially change to “01011001”, “10110010”, 101100100”, “11001000”, “10010000” “00100000”, “01000001” and “10000010” in synchronization with the rising edges of the delayed clock CKD. Since the code C2 outputted from test mode register 326 is “10000010”, the test mode signal TM2 outputted from the code comparator 328 is activated from “0” to “1” when the instruction code IC is changed to “10000010”. Upon this, the semiconductor memory 300 also shifts to the test-pattern-rink test mode in addition to the address-decrement test mode.

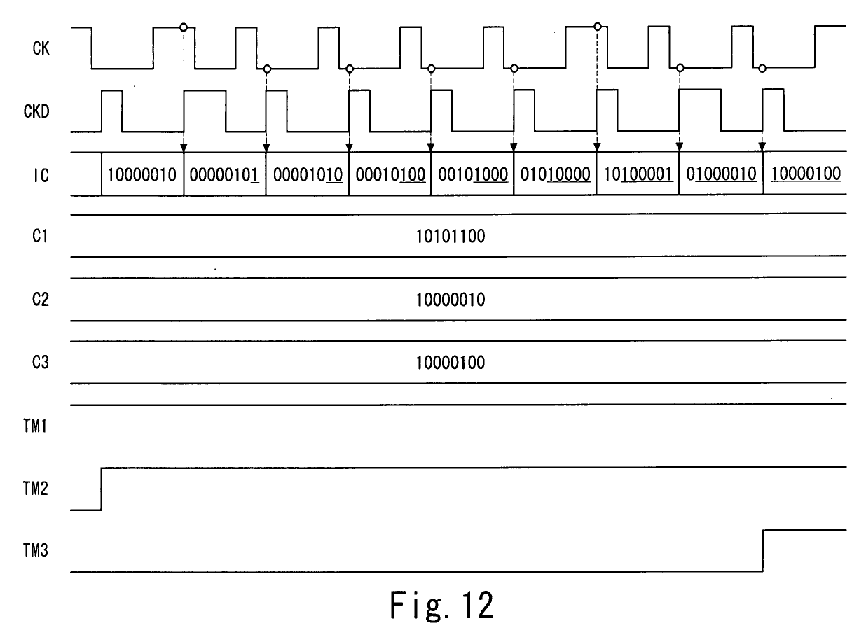

Furthermore, as shown in FIG. 12, when the external clock CK is inputted to the external clock terminal CK while sequentially changing its duty ratio to 50%, 25%, 25%, 25%, 25%, 50%, 25% and 25% in every cycle, levels of the external clock CK sequentially received in synchronization with the rising edges of the delayed clock CKD within the instruction code generator 224 will be “1”, “0”, “0”, “0”, “0”, “1”, “0” and “0”. Accordingly, the instruction code IC outputted from the instruction code generator 224 will sequentially change to “00000101”, “00001010”, “00010100”, “00101000”, “01010000”, “10100001”, “01000010” and “10000100” in synchronization with the rising edges of the delayed clock CKD. Since the code C3 outputted from the test mode register 326 is “10000100”, the test mode signal TM3 outputted from the code comparator 328 is activated from “0” to “1” when the instruction code IC is changed to “10000100”. Upon this, the semiconductor memory 300 also shifts to the address-degeneration test mode, in addition to the address-decrement test mode and the test-pattern-link test mode.

As explained in the above, the effect similar to those of the first and second embodiments may also be obtained from the third embodiment. Furthermore, by inputting the external clock CK to the external clock terminal CK by sequentially changing its duty ratio to have them correspond to multiple test modes (address-decrement test mode, test-pattern-link test mode, and address-degeneration test mode), the semiconductor memory 300 may simultaneously be placed into the multiple test modes that may be performed in parallel. Also, since the register value of the test mode register 326 may be set for each of the semiconductor memory chips on a wafer, it is significantly effective when the necessity arises to perform a separate content of the tests over each of the semiconductor memory chips according to the distribution of the characteristics over the wafer.

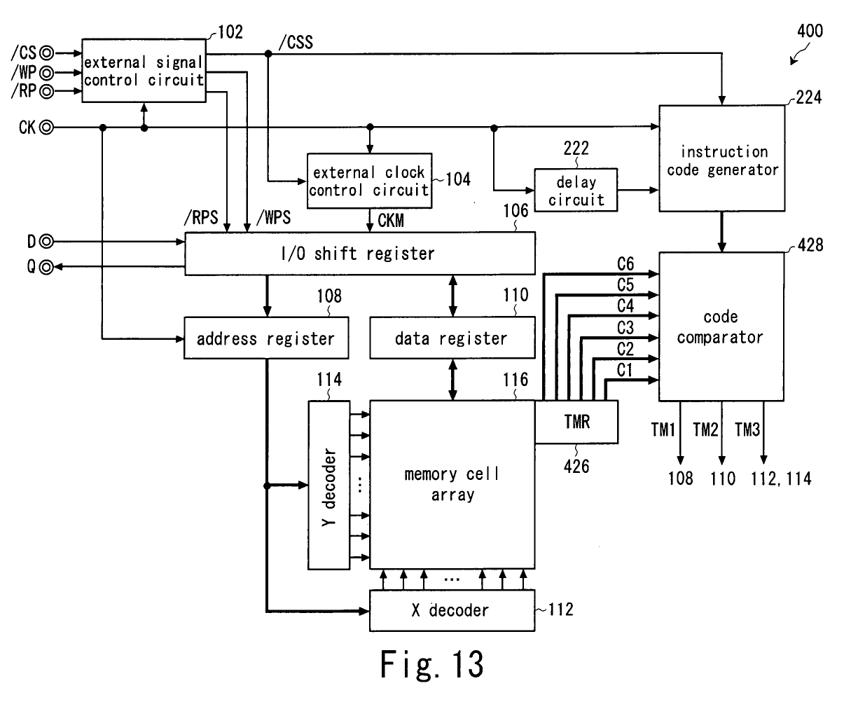

FIG. 13 shows a fourth embodiment of the invention. Any elements identical to those described according to the first through third embodiments will be indicated by the identical numerals and detailed description therefor will be omitted. In addition, the semiconductor device of the invention is constructed as a serial interface type semiconductor memory 400 (i.e. FRAM) similar to the first embodiment. The semiconductor memory 400 includes a test mode register 426 and a code comparator 428 in place of the test mode register 326 and the code comparator 328 of the third embodiment (FIG. 9).

The test mode register 426 is i.e. a 48-bit register, and it includes memory cells identical to those of the memory cell array 116 in the same manner as the test mode register 226 of the second embodiment. The test mode register 426 outputs register values to the code comparator 428 as six 8-bit codes C1-C6. Also, the test mode register 426 is capable of reading and writing the register values in the same way as accessing to the memory cell array 116. For example, at the time of the prove test of the semiconductor memory 400, the test mode register 426 is preset to a register value set including a value representing the address-decrement test mode (“10101100”), a value representing the test-pattern-link test mode (“10000010”), a value representing the address-degeneration test mode (“10000100”) and values respectively representing test-mode permission (“11101110”, “01110111” and “00111011”). Furthermore, in order to inhibit user to set the register values of the test mode register 426 after the shipment of the semiconductor memory 400, an address that inhibits user's access is allocated to the test mode register 426.

The code comparator 428 compares the instruction code IC from the instruction code generator 224 with the codes C4-C6 from the test mode register 426, and when the instruction code IC matches with all of the codes C4-C6, the activation operation of the test mode signals TM1-TM3 is enabled. That is, the code comparator 428 can perform the test-mode shifting control operation when the instruction code IC indicates the test-mode permission. Any other operations of the code comparator 428 are identical to those of the code comparator 328 of the third embodiment.

As explained in the above, the effect that is similar to those of the first through third embodiments may be obtained from the fourth embodiment. Furthermore, the code comparator 428 never activates the test mode signals TM1-TM3 unless the instruction code IC matches all of the codes C4-C6. Accordingly, even when the duty ratio of the external clock CK varies in every cycle due to a noise etc. during the use of the semiconductor memory 400 by a user, it is surely avoidable that the semiconductor memory 400 is shifted to the test mode.

The first through fourth embodiments are explained according to the examples in which the invention is applied to serial interface type FRAMs. The present invention however is not limited to such the embodiments. For example, the invention may be applied to a parallel interface type FRAM, or any other semiconductor devices such as nonvolatile semiconductor memory like flash memory or EEPROM, microcontroller, ASIC etc.

The invention is not limited to the above embodiments and various modifications may be made without departing from the spirit and scope of the invention. Any improvement may be made in part or all of the components.

What is claimed is:

1. A semiconductor device comprising:
a functional block having a normal operation mode and a test mode;
an external signal terminal receiving an operation inhibition signal which is activated to inhibit the normal operation of said functional block;
an external clock terminal receiving an external clock; and
a test mode control circuit that shifts said functional block from the normal operation mode to the test mode while the operation inhibition signal is in an activated state and the test mode control circuit is receiving the external clock.

2. The semiconductor device according to claim 1 wherein said test mode control circuit comprises:
a holding circuit that holds in advance flag information, and outputs the flag information while said test mode control circuit is receiving the external clock, the flag information indicating permission/inhibition for said functional block to shift from the normal operation mode to the test mode; and
a control circuit that activates a test mode signal when the operation inhibition signal is in an active state and the flag information from said holding circuit indicates permission, wherein
said functional block shifts from the normal operation mode to the test mode in response to activation of the test mode signal.

3. The semiconductor device according to claim, 2 wherein
the flag information held in said holding circuit is rewritable.

4. The semiconductor device according to claim 2, wherein:
said functional block is a memory block having nonvolatile memory cells;
to hold the flag information, said holding circuit comprises memory cells that are identical to those of the memory block.

5. A semiconductor device comprising:
a functional block having a normal operation mode and a test mode;
an external clock terminal receiving an external clock whose duty ratio is variable;
a delay circuit that outputs a delayed clock which is generated by delaying the external clock;
an instruction code generator that sequentially receives a level of the external clock in synchronization with a transition edge of the delayed clock and outputs it as an instruction code; and
a test mode control circuit that shifts said functional block from the normal operation mode to the test mode when the instruction code indicates the test mode.

6. The semiconductor device according to claim 5, wherein said test mode control circuit comprises:
a holding circuit that holds in advance a code indicating the test mode and outputs the code; and
a control circuit that activates a test mode signal in response to a coincidence of the instruction code and the code from said holding circuit, wherein
said functional block shifts from the normal operation mode to the test mode in response to activation of the test mode signal.

7. The semiconductor device according to claim 6, wherein
the code held in said holding circuit is rewritable.

8. The semiconductor device according to claim 6, wherein:
said functional block is a memory block having nonvolatile memory cells; and
to hold the code, said holding circuit comprises memory cells that are identical to those of the memory block.

9. The semiconductor device according to claim 5, wherein:
said functional block has a plurality of test modes; and
when the instruction code indicates any of the plurality of test modes, said test mode control circuit shifts said functional block from the normal operation mode to the indicated test mode.

10. The semiconductor device according to claim 9, wherein said test mode control circuit comprises:
a holding circuit that holds in advance a plurality of codes for output, the plurality of codes corresponding to the plurality of test modes; and
a control circuit that activates, in response to a coincidence of the instruction code and any of the plurality of codes from said holding circuit, one of the plurality of test mode signals corresponding to the coinciding code, wherein
in response to activation of any of the plurality of test mode signals, said functional block shifts from the normal operation mode to a test mode that corresponds to the activated test mode signal.

11. The semiconductor device according to claim 10, wherein
the code held in said holding circuit is rewritable.

12. The semiconductor device according to claim 10, wherein:
said functional block is a memory block having nonvolatile memory cells; and
to hold the code, said holding circuit comprises memory cells that are identical to those of the memory block.

13. The semiconductor device according to claim 5, wherein
said test mode control circuit is possible to perform the test-mode control operation on said functional block when the instruction code indicates permission to the test mode, and shifts said functional block from the normal operation mode to the test mode when a subsequent instruction code indicates the test mode.
